(19) United States
(12) Patent Application Publication
(10) Pub. No.: US 2021/0211123 A1
(43) Pub. Date: Jul. 8, 2021

(54) METHOD AND ARRANGEMENT FOR ACTUATING A METAL-OXIDE SEMICONDUCTOR FIELD-EFFECT TRANSISTOR

(71) Applicant: Siemens Aktiengesellschaft, 80333 München (DE)

(72) Inventors: MARK-MATTHIAS BAKRAN, Erlangen (DE); JÜRGEN BÖHMER, Stein (DE); MARTIN HELSPER, Allersberg (DE); EBERHARD ULRICH KRAFFT, Nürnberg (DE); BERND LASKA, Herzogenaurach (DE); ANDREAS NAGEL, Nürnberg (DE); STEFAN HANS WERNER SCHÖNEWOLF, Nürnberg (DE); JAN WEIGEL, Grossenbuch (DE)

(73) Assignee: Siemens Aktiengesellschaft, 80333 München (DE)

(21) Appl. No.: 17/059,130

(22) PCT Filed: May 15, 2019
(86) PCT No.: PCT/EP2019/062457

§ 371 Date: Nov. 25, 2020

(30) Foreign Application Priority Data
May 29, 2018 (EP) 18174802.1

(51) Int. Cl. H03K 17/082; H03K 17/16; H02M 3/158; H02M 1/08

(52) U.S. Cl. CPC H03K 17/0822; H02M 1/08; H02M 3/1588; H03K 17/165

(57) ABSTRACT

With a method and an actuation arrangement for actuating a MOSFET, in particular a wide-bandgap semiconductor MOSFET, a monitoring process is performed to determine whether the body diode of the MOSFET is electrically conducting or blocking. If the body diode is electrically conducting, the MOSFET is activated, and if the body diode is electrically blocking, the MOSFET is actuated in response to an actuation signal generated based on the drain-source voltage and the direction and intensity of the drain-source current of the MOSFET.

The invention relates to a method and an actuation arrangement for actuating a Metal Oxide Semiconductor Field Effect Transistor (MOSFET), in particular a MOSFET based on a semiconductor with a wide bandgap.

A MOSFET is reverse-conducting and has a p-n junction between bulk and drain, which, with an electrical connection between the bulk and source, acts as an intrinsic diode which is referred to as inverse diode or as body diode of the MOSFET. Reverse currents flow through the body diode when the MOSFET is switched off. Since the body diode has a high resistance, high losses occur as a result. Significant losses of this type can occur in particular in a converter embodied in MOSFET technology, when, in the event of a fault, ail MOSFETs of the converter are switched off and reverse currents flow out of a supply network connected to the converter or a load connected to the converter through body diodes of the MOSFET of the converter. At present MOSFETS which are based on semiconductors with a wide bandgap, for instance on silicon carbide or gallium nitride, and are exposed to high current loads are used increasingly in specific converters, for instance in traction converters. In particular, there is therefore the problem in these converters that with an erroneous switching-off of all MOSFETs reverse currents through the MOSFET may result in high losses.

The document Texas Instruments: “UCD7138 4-A and 6-A Single-Channel Synchronous-Rectifier Driver With Body-Diode Conduction Sensing and Reporting”, May 31, 2015 (2015 May 31), URL: http://www.ti.com/lit/ds/symlink/ucd7138.pdf discloses a MOSFET driver with a gate driver, a circuit for detecting a body diode conduction state and a circuit for optimizing a switch-on delay.

The object underlying the invention is to specify a method and an actuation arrangement for actuating a MOSFET, which are improved with respect to the reduction in losses caused by reverse currents.

The object is achieved according to the invention by a method having the features of claim 1 and an actuation arrangement having the features of claim 9.

Advantageous embodiments of the invention form the subject matter of the subclaims.

The inventive method relates to the actuation of a MOSFET, in particular a MOSFET based on a semiconductor with a wide bandgap, having a drain terminal, a source terminal, a gate terminal and a body diode, wherein the MOSFET is arranged in a converter having a number of MOSFETs. Here, after the occurrence of fault, which has resulted in all MOSFETs of the converter switching off, it is monitored to determine whether the body diode of the MOSFET is electrically conducting. The MOSFET is switched on if the body diode is electrically conducting, and the MOSFET is actuated as a function of an actuation signal if the body diode is electrically blocking.

The invention therefore provides to switch on a MOSFET, if its body diode is conducting and thus current-caring, after the occurrence of a fault which has resulted in all MOSFETs of the converter switching off. By switching on the MOSFET, reverse currents, which would flow only through the body diode in the switched-off state of the MOSFET, are carried at least partially through the MOSFET channel between the source terminal and the drain terminal so that reverse currents flowing through the body diode and the losses caused as a result are significantly reduced. If the body diode is electrically blocking, the MOSFET is actuated as is customary as a function of an actuation signal so that in this case the actuation of the MOSFET is not changed.

One embodiment of the invention provides that a first voltage threshold value is predetermined for a drain-source voltage between the drain terminal and the source terminal of the MOSFET, the drain-source voltage is detected and it is concluded therefrom that the body diode is electrically conducting if the drain-source voltage does not reach the first voltage threshold value Furthermore, a second voltage threshold value can be predetermined for the drain-source voltage and it can be concluded therefrom that the body diode is eclectically blocking if the drain-source voltage exceeds the second voltage threshold value. For instance, both voltage threshold values are negative and the second voltage threshold value is larger than the first voltage threshold value.

The afore-cited embodiment of the invention uses the drain-source voltage to identify whether the body diode of the MOSFET is electrically conducting or blocking. To this end, voltage threshold values are used, the failure to reach or the exceeding thereof signals that the body diode is electrically conducting or blocking.

A further embodiment of lie invention provides that a first current threshold value is predetermined for a drain-source current intensity of a drain-source current flowing in a forward direction of the body diode between the drain terminal and the source terminal of the MOSFET, the drain-source current intensity is detected and it is concluded therefrom that the body diode is electrically conducting if the drain-source current intensity exceeds the first current threshold value. Furthermore, a second current threshold value can be predetermined for the drain-source current intensity, which is smaller than the first current threshold value, and it can be concluded therefrom that the body diode is electrically blocking if the drain-source current intensity does not reach the second current threshold value.

A further embodiment of the invention provides that the direction of a drain-source current flowing between the drain terminal and the source terminal of the MOSFET is detected, and it is concluded therefrom that the body diode is electrically conducting if the drain-source current flows in a forward direction of the body diode. Furthermore, it can be concluded therefrom that the body diode is electrically blocking if the drain-source current flows in the opposite direction to the forward direction of the body diode.

The afore-cited embodiments of the invention use the drain-source current to identify whether the body diode is electrically conducting or blocking. To this end, current threshold values are used for the current intensity of the drain-source current in the forward direction of the body diode, the failure to reach or the exceeding thereof signal that the body diode is electrically conducting or blocking. The drain-source current intensity is measured for instance with a shunt resistor, which is arranged in the current path of the drain-source current. Alternatively or in addition, the direction of the drain-source current is detected to identify whether the body diode is electrically conducting or blocking. The direction of the drain-source current is determined for instance by counting the triggered voltage pulses or by means of a flip flop which changes its stale with each triggered voltage pulse.

An inventive actuation arrangement for carrying out the inventive method comprises a monitoring unit, which is embodied to determine whether the body diode is electrically conducting or blocking, and a control unit, which is embodied to switch on the MOSFET after the occurrence of a fault, which has resulted in all MOSFETS of the converter switching off, if the monitoring unit determines that the body diode is electrically conducting, and to actuate the MOSFET as a function of the actuation signal if the body diode is electrically blocking.

Embodiments of the inventive actuation arrangement provide that the monitoring unit is embodied to detect the drain-source voltage and to determine on the basis of the drain-source voltage whether the body diode is electrically conducting or blocking, or/and that the monitoring unit is embodied to detect the drain-source current intensity and on the basis of the drain-source current intensity to determine whether the body diode is electrically conducting or blocking, and/or that the monitoring unit is embodied to detect the direction of the drain-source current and on the basis of the direction of the drain-source current to determine whether the body diode is electrically conducting or blocking.

A further embodiment of the inventive actuation arrangement provides that the monitoring unit is embodied to communicate to the control unit by means of an additional actuation signal whether the body diode is electrically conducting or blocking, and the control unit has an end stage for actuating the MOSFET as a function of the additional actuation signal and the actuation signal. An alternative embodiment of the inventive actuation arrangement provides that the monitoring unit is embodied to communicate to the control unit by means of an additional actuation signal whether the body diode is electrically conducting or blocking, and the control unit has a first end stage for actuating the MOSFET as a function of the actuation signal in the event that the body diode is electrically blocking, and a second end stage for actuating the MOSFET as a function of the additional actuation signal in the event that the body diode is electrically conducting.

An inventive actuation arrangement makes it possible to carry out the inventive method. The advantages of an inventive actuation arrangement therefore correspond to the advantages of the inventive method already cited above and are not specified here again separately.

Overall, the invention modifies the actuation of a MOSFET only after the occurrence of a fault, which has resulted in all MOSFETs of the converter switching off, in the event that the body diode is electrically conducting. To this end, an actuation arrangement is used, which expands the typical actuation by the additional function in order to switch on the MOSFET after the occurrence of the fault when the body diode is electrically conducting. Besides this, the typical actuation of the MOSFET and the typical protective concept of the invention remain unaffected.

An inventive converter, in particular a traction converter, has a number of MOSFETs, in particular a number of MOSFETs based in each case on a semiconductor with a wide bandgap. and for each MOSFET an inventive actuation arrangement for actuating the MOSFET. The invention is suited in particular to actuating a MOSFET of a traction converter, since current loads of a MOSFET of a traction converter, in particular by means of reverse currents, can be very high and therefore cause high losses.

The above-described characteristics, features and advantages of this invention, as well as the manner in which these are realized will become more clearly and easily intelligible in connection with the following description of exemplary embodiments which are explained in mere detail with reference to the drawings, in which;

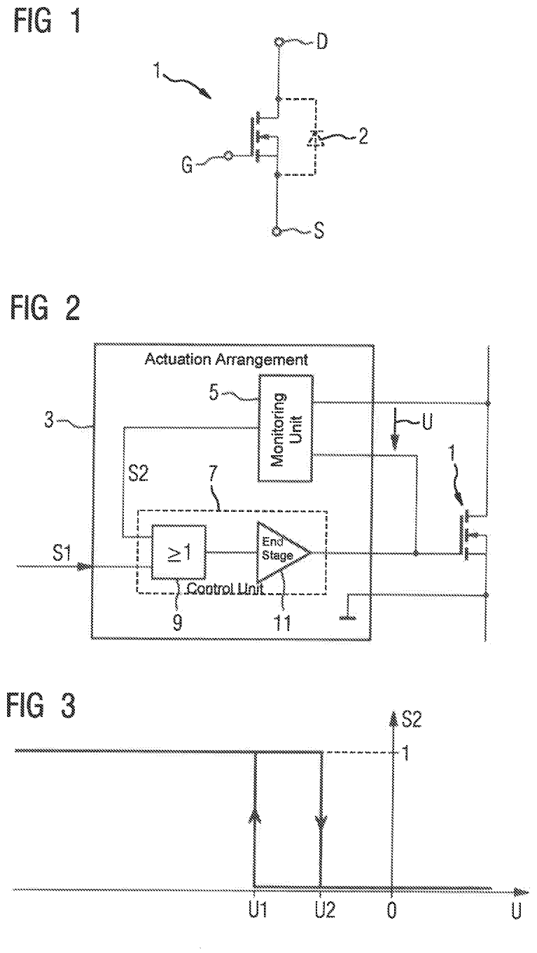

FIG. 1 shows a circuit diagram of a MOSFET,

FIG. 2 shows a circuit diagram of a MOSFET and a first exemplary embodiment of an actuation arrangement for actuating the MOSFET,

FIG. 3 shows an additional actuation signal as a function of a drain-source voltage of a MOSFET,

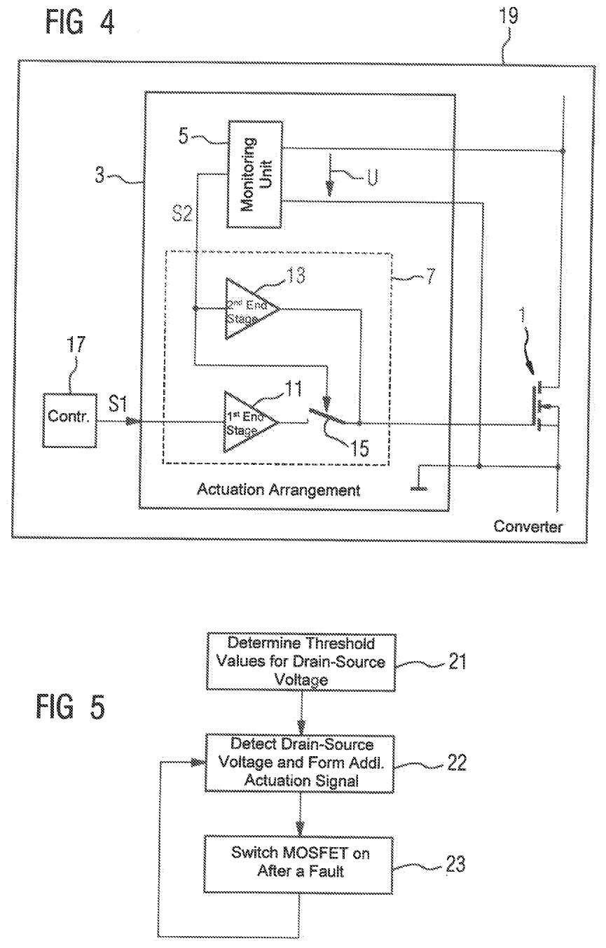

FIG. 4 shows a circuit diagram of a converter,

FIG. 5 shows a flow chart of a method for actuating a MOSFET.

Parts which correspond to one another are provided with the same reference characters in the figures.

FIG. 1 shows a circuit diagram of a MOSFET 1 with a drain terminal D, a source terminal S, a gate terminal G and a body diode 2. The MOSFET 1 is embodied as a normally blocking n-channel MOSFET, which is based on a semiconductor with a wide bandgap, for instance on silicon carbide or gallium nitride. Reverse currents, in other words currents which (according to the technical flow direction) are directed from the source terminal S to the drain terminal D, flow through the body diode 2 when the MOSFET 1 is switched off.

FIG. 2 shows a circuit diagram of a MOSFET 1 embodied as in FIG. 1 and a first exemplary embodiment of an inventive actuation arrangement 3 for actuating the MOSFET 1.

The actuation arrangement 3 comprises a monitoring unit 5 and a control unit 7. The monitoring unit 5 is embodied to determine whether the body diode 2 of the MOSFET 1 is electrically conducting or blocking and to communicate this to the control unit 7. To this end, the monitoring unit 5 detects a drain-source voltage U between the drain terminal D and the source terminal S of the MOSFET 1 and outputs a binary additional actuation signal S2 which depends on the drain-source voltage U to the control unit 7, which assumes the value 0 or the value 1. The value 1 of the additional actuation signal S2 signals that the body diode 2 is electrically conducting. The value 0 of the additional actuation signal S2 signals that the body diode 2 is electrically blocking.

FIG. 3 shows the additional actuation signal S2 output by the monitoring unit 5 as a function of the drain-source voltage U. The additional actuation signal S2 assumes the value 1 if the drain-source voltage U does not reach a predetermined first voltage threshold value U1. The additional actuation signal S2 assumes the value 0 if the drain-source voltage U exceeds a predetermined second voltage threshold value U2. Both voltage threshold values U1, U2 are negative, wherein the second voltage threshold value U2 is greater than the first voltage threshold value U1. For instance, the first voltage threshold value U1 has a value of approx. −1V and the second voltage threshold value U2 has a value of approx. −0.5V. With values of the drain-source voltage U, which lie between the two voltage threshold values U1, U2. the additional actuation signal S2 is not changed, in other words it retains its current value.

The MOSFET 1 is arranged in a converter 19. which has a number of MOSFETs 1 (see also FIG. 4). The control unit 7 actuates the MOSFET 1 as a function of a binary actuation signal S1, which assumes the value 0 or the value 1, and after the occurrence of a fault, which has resulted in all MOSFETs 1 of the converter 19 switching off, in addition as a function of the additional actuation signal S2. To this end, the control unit 7 has an OR gate 9 and an end stage 11. The actuation signal S1 and the additional actuation signal S2 are supplied to the OR gate 9. The OR gate 9 outputs the value 0 to the end stage 11, when both the actuation signal S1 and also the additional actuation signal S2 assume the value 0. On the other hand the OR gate 9 specifies the value 1 to the end stage 11. If the OR gate 9 outputs the value 1, the end stage 11 switches on the MOSFET 1, by it applying a positive switch-on voltage between the gate terminal G and the source terminal S of the MOSFET 1. On the other hand, the end stage 11 switches off the MOSFET 1, by it applying a switch-off voltage between the gate terminal G and the source terminal S of the MOSFET 1.

FIG. 4 shows a circuit diagram of a conductor 19 with a MOSFET 1 and a second exemplary embodiment of an inventive actuation arrangement 3 for actuating the MOSFET 1. For instance, the converter 19 is a traction converter with further MOSFETs 1 (not shown here), which are wired in a known manner to form half or full bridges, and a further actuation arrangement 3 for each further MOSFET 1.

The actuation arrangements 3 of this exemplary embodiment differ from the exemplary embodiment shown in FIG. 2 only by the embodiment of the control units 7. A control unit 7 of this exemplary embodiment has two end stages 11,13 and one switch 15. An actuation signal SI is supplied to a first end stage 11. The additional actuation signal S2 output by the monitoring unit 5 of the respective actuation arrangement 3 is supplied to the second end stage 13 after the occurrence of a fault, which has resulted in all MOSFETs 1 of the converter 19 switching off. The switch 15 separates an output of the first end stage 11 from the gate terminal G of the MOSFET 1 actuated by the actuation arrangement 3 if the additional actuation signal S2 assumes the value 1. In this case, the MOSFET 1 is switched on by the second end stage 13, by the second end stage 13 applying a positive switch-on voltage between the gate terminal G and the source terminal S of the MOSFET 1. If the additional actuation signal S2 assumes the value 0, the output of the first end stage 11 is connected by the switch 15 to the gate terminal G of the MOSFET 1 actuated by the actuation arrangement 3 and the MOSFET 1 is actuated by the first end stage 11, in other words by the second end stage 13 no voltage is applied between the gate terminal G and the source terminal S of the MOSFET 1 and the MOSFET 1 is switched on by the first end stage 11 if the actuation signal S1 assumes the value 1, and is switched off if the actuation signal S1 assumes the value 0.

The actuation signals S1 for the MOSFETs 1 of the converter 19 are generated by a controller 17 of the converter 19. Provision can be made for the actuation of the MOSFETs 1 only to be activated as a function of the additional actuation signals S2 by the second end stages 13 when the controller 17 approves this.

FIG. 5 shows a flow chart of an exemplary embodiment of the inventive method for actuating a MOSFET 1 with an actuation arrangement 3 embodied according to FIG. 2 or FIG. 4.

In a first method step 21, the voltage threshold values U1, U2 are predetermined for the drain-source voltage U.

In a second method step 22, the drain-source voltage U is detected by the monitoring unit 5, and the additional actuation signal S2 is formed as a function of the drain-source voltage U in the manner described above on the basis of FIG. 3 and output to the control unit 7.

In a third method step 23, the MOSFET 1 is switched on by the control unit 7 after the occurrence of a fault, which has resulted in all MOSFETs 1 of the converter 19 being switched off, in other words a switch-on voltage is applied between the gate terminal G and the source terminal S of the MOSFET 1, if the additional actuation signal S2 assumes the value 1. On the other hand, the MOSFET 1 is actuated by the control unit 7 as a function of the actuation signal S1, in other words the switch-on voltage is applied between the gate terminal G and the source terminal S of the MOSFET 1, if the actuation signal S1 assumes the value 1, or a switch-off voltage is applied between the gate terminal G and the source terminal S of the MOSFET 1, if the actuation signal S1 assumes the value 0. After the third method step 23, the method is continued with the second method step 22.

The exemplary embodiments of an inventive actuation arrangement 3 and the inventive method described above on the basis of the figures can be modified in a variety of ways to form alternative exemplary embodiments. In particular, the monitoring unit 5 can be embodied in a different manner to the exemplary embodiments described above on the basis of the figures.

For instance, the monitoring unit 5 can be embodied to detect and evaluate, instead of the drain-source voltage U, a drain-source current intensity of a drain-source current flowing in a forward direction of the body diode 2 between the drain terminal D and the source terminal S. In this case, a first current threshold value for the drain-source current intensity and a second current threshold value for the drain-source current intensity, which is less than the first current threshold value, are predetermined. The additional actuation signal S2 is set to the value 1 if the drain-source current intensity exceeds the first current threshold value. The additional actuation signal S2 is set to the value 0 if the drain-source current intensity does not reach the first current threshold value. With drain-source current intensity values which lie between the two current threshold values, the additional actuation signal S2 is not changed, in other words it retains its current value. The drain-source current intensity is measured for instance with a shunt resistor, which is arranged in the current path of the drain-source current.

Alternatively, the monitoring unit 5 can be embodied to detect a direction of the drain-source current. In this case, the additional actuation signal S2 is set to the value 1, if the drain-source current flows in the forward direction of the body diode 2. On the other hand, the additional actuation signal S2 is set to the value 0. For instance, the direction of the drain-source current is determined using a ferromagnetic core, which triggers a voltage pulse with each change in direction of the drain-source current.

The direction of the drain-source current is determined for instance by counting the triggered voltage pulses or by means of a flipflop, which changes its state with each triggered voltage pulse.

Alternative exemplary embodiments of a converter 19 to FIG. 4 are produced by replacing the actuation arrangement 3 shown in FIG. 4 by an actuation arrangement 3 of the exemplary embodiment described in FIG. 2 or one of the afore-cited modified exemplary embodiments.

Although the invention has been illustrated and described in detail based on preferred exemplary embodiments, the invention is not restricted by the examples given and other variations can be derived therefrom by a person skilled in the art without departing from the protective scope of the invention.

1-15. (canceled)

16. A method for actuating a Metal Oxide Semiconductor Field Effect Transistor (MOSFET), in particular a wide bandgap semiconductor MOSFET, of a converter having a plurality of MOSFETs, said method comprising:
predetermining a first voltage threshold value and a second voltage threshold value for the drain-source voltage;
detecting a drain-source voltage between a drain terminal and a source terminal of the MOSFET, and measuring a direction of a drain-source current flowing between the drain terminal and the source terminal of the MOSFET;
after an occurrence of a fault which causes all MOSFETs of the converter being switching off, monitoring whether a body diode of the MOSFET is electrically conducting, concluding that the body diode is electrically conducting when the drain-source current flows in a forward direction of the body diode and the drain-source voltage fails to reach the first voltage threshold value, and concluding that the body diode is electrically blocking when the drain-source current flows in a reverse direction of the body diode and the drain-source voltage exceeds the second voltage threshold value, and
switching the MOSFET on as a function of an actuation signal when the body diode is electrically conducting.

17. The method of claim 16, wherein both the first voltage threshold value and the second voltage threshold value are negative and the second voltage threshold value is greater than the first voltage threshold value.

18. The method of claim 16, further comprising:
predetermining a first current threshold value for the drain-source current flowing in the forward direction of the body diode,
measuring the drain-source current, and
concluding that the body diode is electrically conducting when the drain-source current exceeds the first voltage threshold value.

19. The method of claim 18, further comprising:
predetermining a second current threshold value for the drain-source current, which is smaller than the first current threshold value, and
concluding that the body diode is electrically blocking when the drain-source current is less than the second current threshold value.

20. The method of claim 16, further comprising:
detecting with a monitoring unit the drain-source voltage and forming an additional actuation signal as a function of the drain-source voltage and outputting the additional actuation signal to a control unit, and
switching the MOSFET on with the control unit after an occurrence of an error which caused all MOSFETs of the converter to be switched off.

21. The method of claim 20, further comprising:
applying a switch-on voltage between the gate terminal and the source terminal of the MOSFET when the additional actuation signal assumes the value 1, or
applying the switch-on voltage between the gate terminal and the source terminal of the MOSFET in response to the actuation signal when the actuation signal assumes a value of 1, or
applying a switch-off voltage between the gate terminal and the source terminal of the MOSFET when the actuation signal assumes a value of 0, and
continuing detecting the drain-source voltage with the monitoring unit and continuing forming the additional actuation signal and outputting the additional actuation signal to the control unit.

22. An actuation arrangement for actuating a Metal Oxide Semiconductor Field Effect Transistor (MOSFET), in particular a wide bandgap semiconductor MOSFET, of a converter having a plurality of MOSFETs, said actuation arrangement comprising:
a monitoring unit receiving from the MOSFET an input signal indicating a drain-source voltage and a drain-source current intensity and direction, and determining based on the drain-source voltage and the drain-source current intensity and direction whether a body diode of the MOSFET is electrically conducting or blocking, and
a control unit connected to a gate of the MOSFET and configured to actuate the MOSFET, after occurrence of a fault which causes all MOSFETs of the converter to be switched off, when the monitoring unit determines that the body diode is electrically conducting, and to actuate the MOSFET as a function of an actuation signal when the monitoring unit determines that the body diode is electrically blocking.

23. The actuation arrangement of claim 22, wherein the monitoring unit transmits to the control unit an additional actuation signal that indicates whether the body diode is electrically conducting or blocking, and wherein the control unit comprises an end stage for actuating the MOSFET as a function of the actuation signal and the additional actuation signal.

24. The actuation arrangement of claim 23, wherein the end stage actuates the MOSFET as a function of the actuation signal when the body diode is electrically blocking, and wherein the control unit comprises a second end stage for actuating the MOSFET as a function of the additional actuation signal when the body diode is electrically conducting.

25. A converter having a plurality of Metal Oxide Semiconductor Field Effect Transistors (MOSFETs), comprising each MOSFET of the plurality of MOSFETs an actuation arrangement for actuating a respective MOSFET, said actuation arrangement comprising
a monitoring unit receiving from the respective MOSFET an input signal indicating a drain-source voltage and a drain-source current intensity and direction, and determining based on the drain-source voltage and the drain-source current intensity and direction whether a body diode of the respective MOSFET is electrically conducting or blocking, and
a control unit connected to a gate of the respective MOSFET and configured to actuate the respective MOSFET, either after occurrence of a fault which causes all MOSFETs of the converter to be switched off, as a function of an actuation signal if the body diode is electrically conducting, or when the monitoring unit determines that the body diode of the respective MOSFET is electrically blocking.

26. The converter of claim 25, wherein the converter is a traction converter.
